(19) United States
(12) Patent Application Publication
(10) Pub. No.: US 2026/0016232 A1
(43) Pub. Date: Jan. 15, 2026

(54) WATER-COOLING RADIATOR STRUCTURE WITH A PUMP MODULE

(71) Applicant: JIETE TECHNOLOGY CO.,LTD, Qingyuan (CN)

(72) Inventor: ANDING FANG, Qingyuan (CN)

(21) Appl. No.: 18/806,162

(22) Filed: Aug. 15, 2024

(30) Foreign Application Priority Data
Jul. 9, 2024 (CN) 202421618861.1

(51) Int. Cl. F28D 1/053; F28F 13/06

(52) U.S. Cl. CPC F28D 1/05316; F28F 13/06; F28F 2250/08

(57) ABSTRACT

The present invention discloses a water-cooling radiator structure with a pump module, including a radiator and a water tank. The radiator comprises multiple water pipes spaced apart and two water chambers that connect both ends of the water pipes. The two water chambers include the first water chamber and the second water chamber. Heat dissipation fins are installed between the water pipes. The water tank is equipped with a length that matches either the length of the water chamber or the length of the water pipes, and the water tank is located at least at the first water chamber and/or the second water chamber or connects the two water chambers; The water tank is detachable and is equipped with a pump that provides driving force to the fluid within the water tank, thereby enabling heat exchange between the hot end and the cold end of the fluid.

### CROSS-REFERENCE TO RELATED APPLICATIONS

This application claims priority to Chinese Patent Application No. 202421618861.1, filed on July 09, 2024, which is hereby incorporated by reference in its entirety.

### TECHNICAL FIELD

The present invention relates to the field of water cooling radiators, particularly to a water-cooling radiator structure with a pump module.

### BACKGROUND

Water cooling systems utilize a pump to circulate coolant within heat dissipation pipes and facilitate heat dissipation. The heat-absorbing part on the radiator (referred to as the Heat-absorbing Box in liquid cooling systems) absorbs heat from computer CPUs, North Bridge Chipset, and graphics cards. The heat absorbed by the heat-absorbing part is dissipated to the outside of the main unit through the radiator designed on the back of the chassis.

Existing pump modules for integrating with water cooling radiators require complex water channels, resulting in higher production and assembly costs. For example, Chinese patent CN202022819545.9 achieves an integrated setup through the combination of a pump and a collection box.

### SUMMARY

The primary objective of the present invention is to provide a water-cooling radiator structure with a pump module, designed to modularize the pump for easy integration with or separate use from the water cooling radiator, offering diverse combinations and a simple, stable structure.

To achieve this objective, the present invention proposes a water-cooling radiator structure with a pump module, including:

A radiator, which includes multiple water pipes spaced apart and two water chambers connecting both ends of the water pipes. The two water chambers include the first water chamber and the second water chamber, and heat dissipation fins are installed between the water pipes;

A water tank, which has a length that matches either the length of the water chamber or the length of the water pipes, and is located at least at the first water chamber and/or the second water chamber, or connects the two water chambers;

The water tank is detachable and is equipped with a pump that provides driving force to the fluid within the water tank, thereby enabling heat exchange between the hot end and the cold end of the fluid.

In the actual design, by integrating the water tank and the pump as a module, the water tank can accommodate more liquid, thereby ensuring heat exchange efficiency. At the same time, the detachable water tank module allows for easy replacement or maintenance of the module, effectively improving installation efficiency. For instance, if it is necessary to increase the fluid flow rate, the water tank can be replaced.

In the first embodiment, the water tank is positioned on the upper wall or outer side wall of the water chamber, and the pump is configured with two sets of water pipes (each set consisting of multiple individual water pipes), namely, the inlet set and the outlet set, with partitions to segment the first water chamber or second water chamber.

That is, when one water tank is used, it can be set up in the first water chamber or second water chamber;

In the second embodiment, when two water tanks are used, each water chamber (the first water chamber and second water chamber) will be equipped with a water tank;

In the third embodiment, when one water tank is used, its length matches the length of the water pipes, thus the first water chamber and second water chamber are connected (e.g., positioned at both ends or the upper wall of the water chamber).

### BRIEF DESCRIPTION OF DRAWINGS

FIG. 1 is the perspective view showing the radiator and water tank module in a separated state.

FIG. 2 is sectional view 1 of the present invention.

FIG. 3 is sectional view 2 of the present invention.

FIG. 4 is sectional view 3 of the present invention.

FIG. 5 is sectional view 4 of the present invention.

FIG. 6 is sectional view 5 of the present invention.

FIG. 7 is sectional view 6 of the present invention.

### In the Figures:

1 represents the radiator, 10 represents the water pipe, 11 represents the first water chamber, 12 represents the second water chamber, 13 represents the heat dissipation fins,

2 represents the water tank,

3 represents the pump, 31 represents the positioning base, 32 represents the positioning groove, 33 represents the magnetic sensing coil, 34 represents the Impeller, 35 represents the surrounding portion,

42 represents the inlet tube, 41 represents the outlet tube,

52 represents the inlet guiding hole, 51 represents the outlet guiding hole,

6 represents the first partition.

### DESCRIPTION OF EMBODIMENTS

Next, in conjunction with the attached figures, clear and complete descriptions of the technical solution in the embodiments of the present invention will be stated. Obviously, the described embodiments are only some parts, not the whole ones. Based on the embodiments in the invention, all the other embodiments obtained on the premise that those of ordinary skill in the art do not contribute creative labor belong to the scope of protection of the invention.

It should be noted that if the embodiment of the utility model involves directional indications (such as upper, lower, left, right, front, back, top, bottom, inside, outside, vertical, transverse, longitudinal, counterclockwise, clockwise, circumferential, radial, axial, etc.), the directionality indications are only used to explain the relative positional relationship and motion situation among the components under a certain posture (as shown in the attached figures). If the specific posture changes, the directional indications will also change accordingly.

In addition, if there is a description of "first" or "second" in the embodiment of the utility model, the description of the "first" or "second" is only used for the description purpose but shall not be understood as indicating or implying the relative importance or implicitly indicating the quantity of the technical features. Thus, features defined as "first" and "second" may explicitly or implicitly include at least one feature. In addition, the technical schemes between all the embodiments can be mutually combined, but the combination must be based on the situation that the combination can be achieved by those of ordinary skill in the art, when the combination of the technical schemes has mutual contradiction or cannot be achieved, it should be thought that the combination of the technical schemes does not exist, and the combination is not within the scope of protection required by the invention.

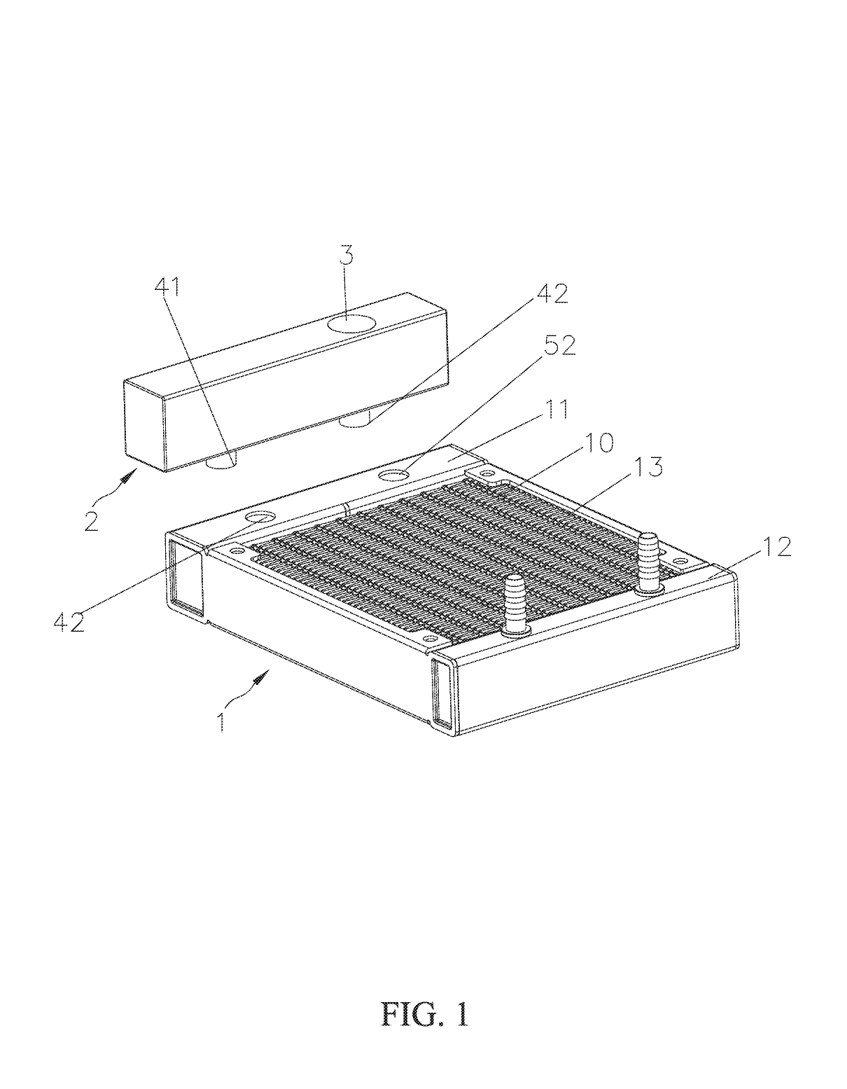

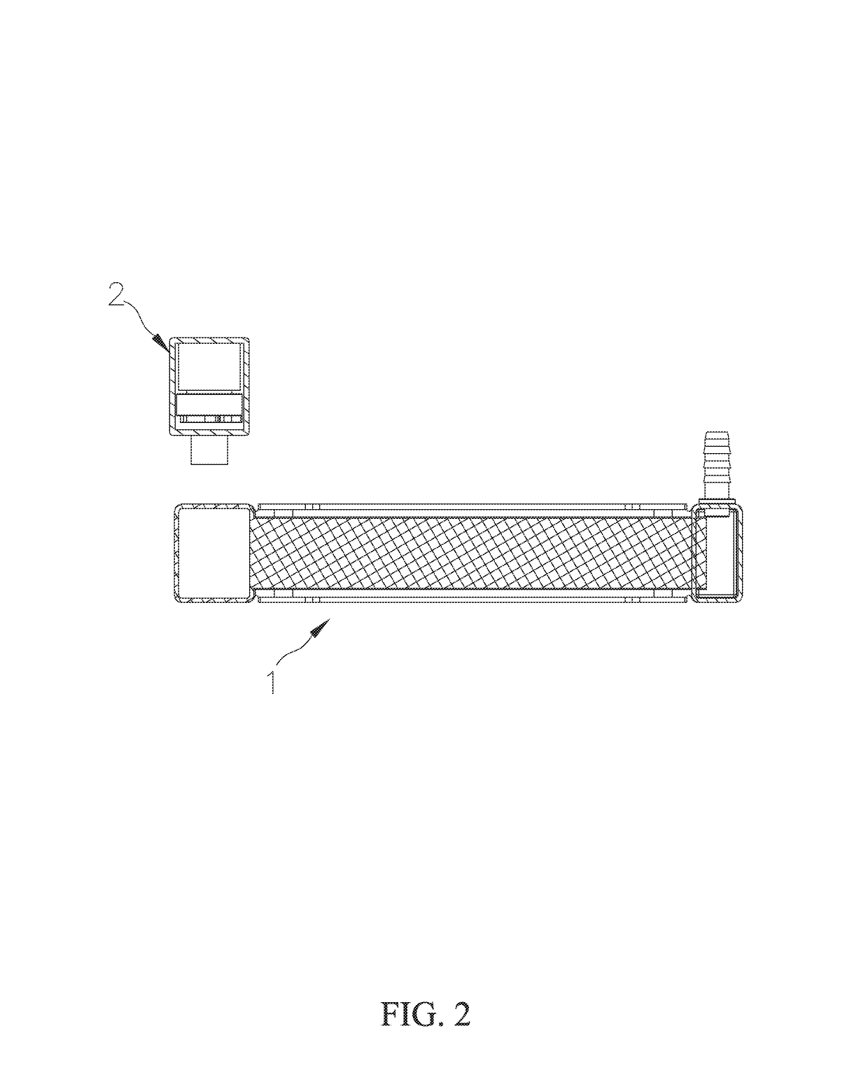

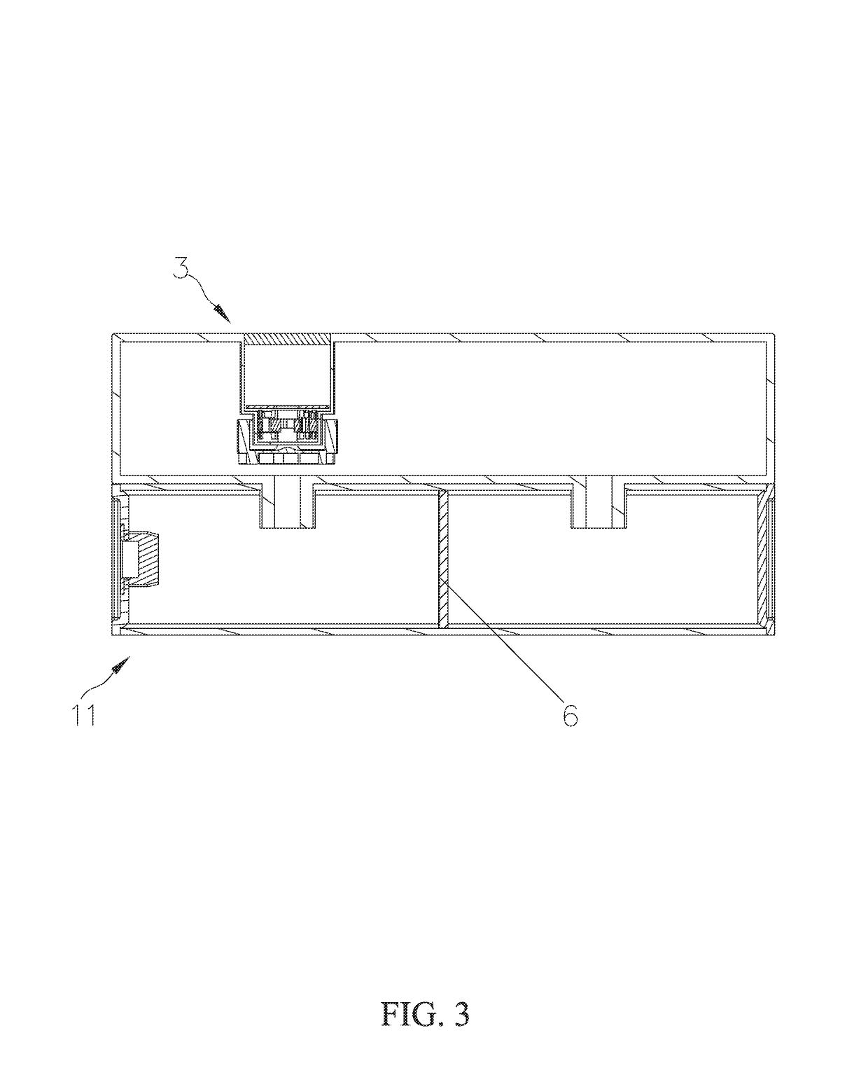

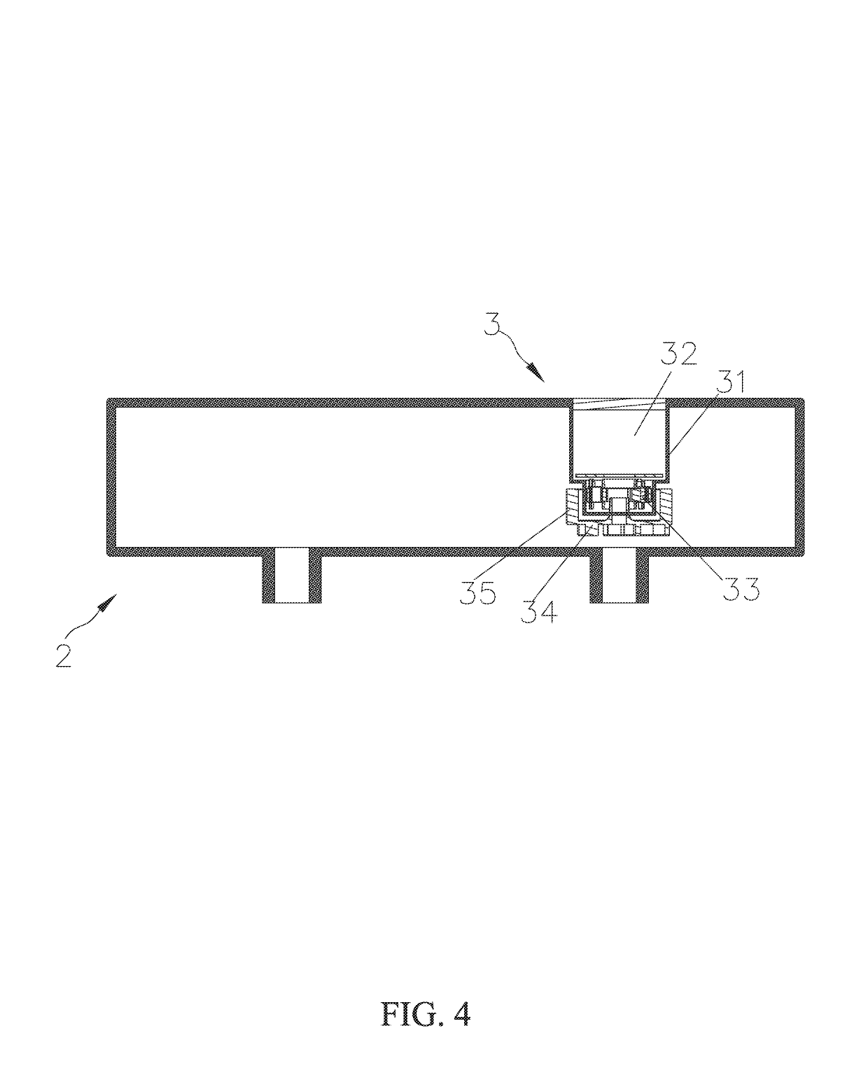

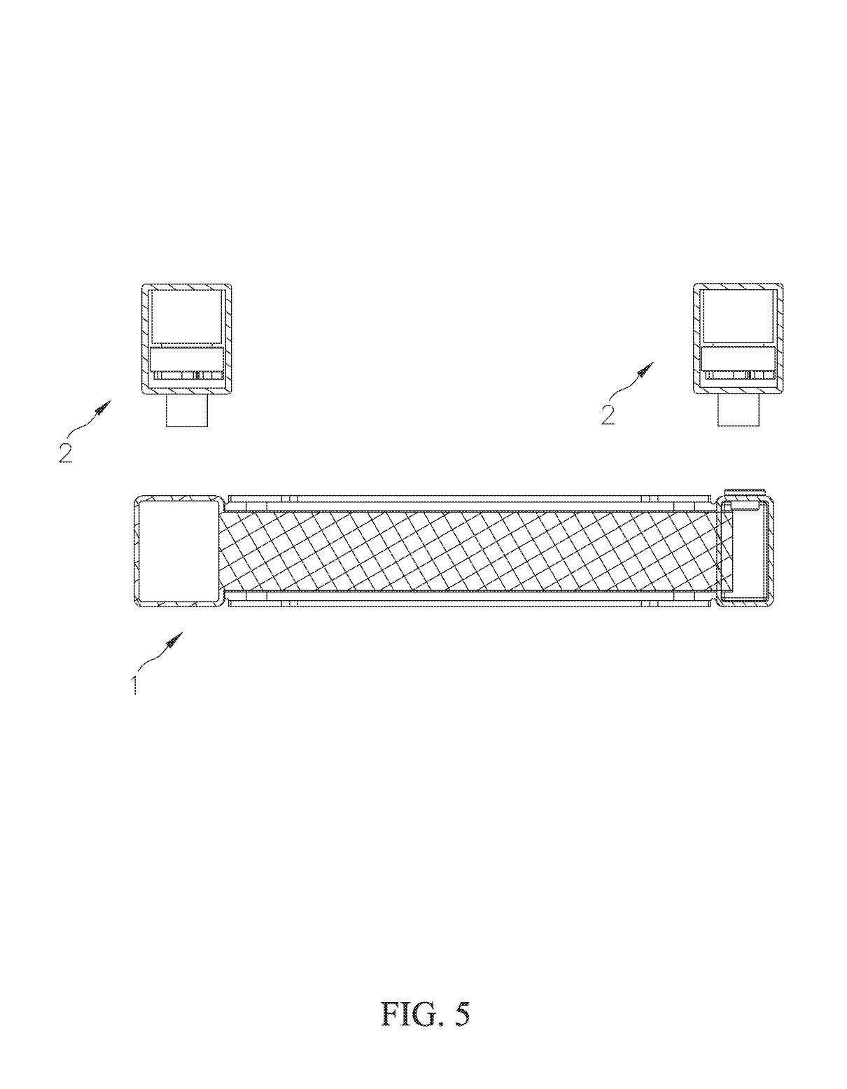

As shown in FIG. 1 to FIG. 7, a water-cooling radiator structure with a pump module comprises:

A radiator 1, which includes multiple water pipes 10 spaced apart and two water chambers connecting both ends of the water pipes 10. The two water chambers include the first water chamber 11 and the second water chamber 12, and heat dissipation fins 13 is installed between the water pipes 10;

A water tank 2, which has a length that matches either the length of the water chamber or the length of the water pipes 10. The water tank 2 is located at least at the first water chamber 11 and/or the second water chamber 12, or the water tank 2 connects the two water chambers;

The water tank 2 is detachable and is equipped with the pump 3 that provides driving force to the fluid within the water tank 2, thereby enabling heat exchange between the hot end and the cold end of the fluid.

In the actual design, by integrating the water tank 2 and the pump 3 as a module, the water tank 2 can accommodate more liquid, thereby ensuring heat exchange efficiency. At the same time, the detachable water tank 2 module allows for easy replacement or maintenance of the module, effectively improving installation efficiency. For instance, if it is necessary to increase the fluid flow rate, the water tank 2 can be replaced.

In the first embodiment, the water tank 2 is positioned on the upper wall or outer side wall of the water chamber, and the pump 3 is configured with two sets of water pipes 10 (each set consisting of multiple individual water pipes 10), namely, the inlet set and the outlet set, with partitions to segment the first water chamber 11 or second water chamber 12.

That is, when one water tank 2 is used, it can be set up in the first water chamber 11 or second water chamber 12;

In the second embodiment, when two water tanks 2 are used, each water chamber (the first water chamber 11 and second water chamber 12) will be equipped with the water tank 2;

In the third embodiment, when one water tank 2 is used, its length matches the length of the water pipes 10, thus the first water chamber 11 and second water chamber 12 are connected (e.g., positioned at both ends or the upper wall of the water chamber).

Specifically, the water tank 2 is located on the upper wall or the outer side wall of the water chamber, where the outer side wall includes the side wall of the water chamber that is away from the water pipes 10 or the end walls at both ends of the water chamber.

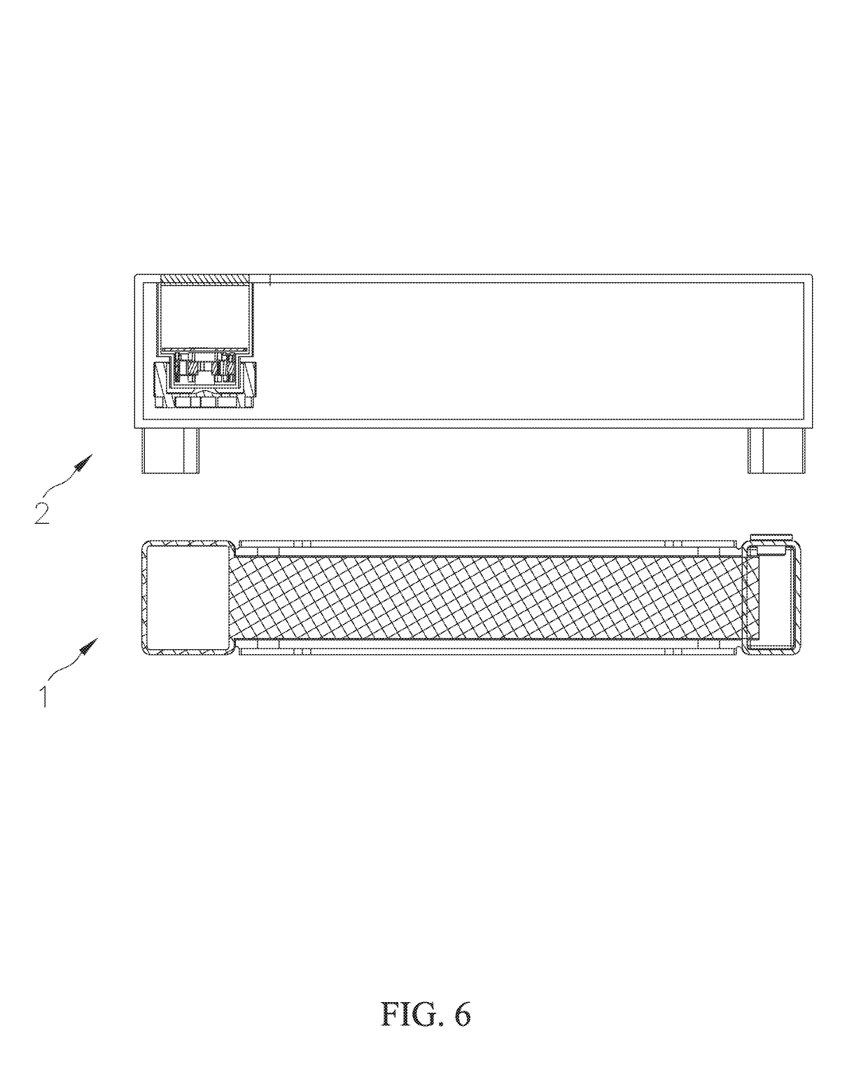

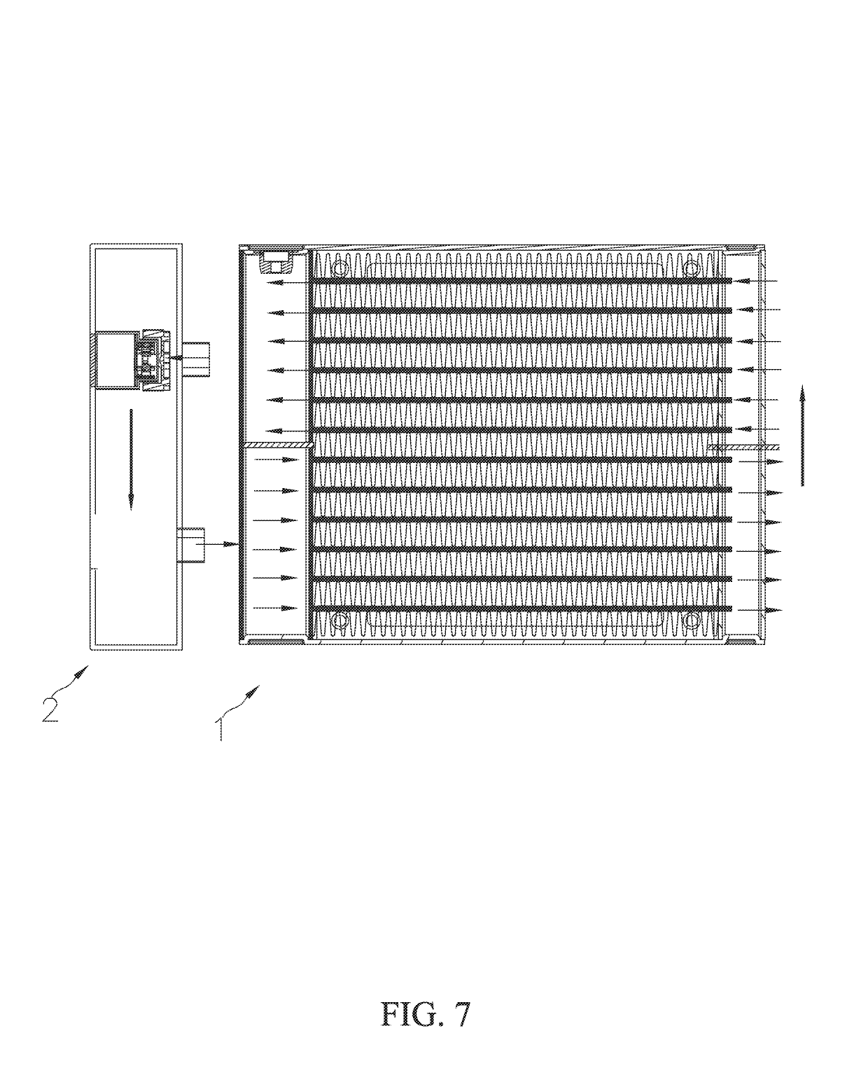

The installation can be adjusted based on actual needs: For example, as shown in FIGS. 1 to 5, the water tank 2 is positioned on the upper wall of the water chamber; as shown in FIG. 6, the water tank 2 is positioned on the end wall of the water chamber; and as shown in FIG. 7, the water tank 2 is positioned on the side wall of the water chamber that is away from the water pipes 10.

In the embodiments of the present invention, the wall surface of the water tank 2 is equipped with spaced inlet tube 42 and outlet tube 41. The water chamber is provided with inlet guiding hole 52 and outlet guiding hole 51 that correspond to the inlet tube 42 and outlet tube 41, respectively. The inlet tube 42 can be inserted into the inlet guiding hole 52, and the outlet tube 41 can be inserted into the outlet guiding hole 51. For example, the first water chamber 11 and the second water chamber 12 each have their own inlet guiding hole 52 and outlet guiding hole 51, or the inlet guiding hole 52 and outlet guiding hole 51 can be located in the same water chamber.

Specifically, the number and arrangement of the inlet tube and outlet tube can vary based on the design of the flow channels.

For practical installation, it is preferable to use a sealing snap-fit structure to secure the pipe body to the guiding holes. Alternatively, snaps or screws can be used to ensure the relative fixation and sealing of the water tank 2 and the water chamber.

Specifically, the first water chamber is equipped with inlet tube 42 and outlet tube 41. The first inner chamber of the first water chamber 11 is equipped with the first partition 6, and the second water chamber 12 is equipped with spaced cooling outlet passage and cooling inlet passage.

In the embodiments of the present invention, the second inner chamber of the second water chamber 12 is equipped with the second partition. However, the absence of partitions can also direct the fluid to flow in a single direction, as shown in FIG. 7 where the second partition is not present. The specific water channels can surely be customized according to actual requirements. Specifically, adjacent water pipes are connected end-to-end in series.

In the embodiments of the present invention, the water pipes are arranged in two sets, including the hot end water pipe group and cold end water pipe group, as shown in FIG. 7.

Specifically, the length of the water tank 2 matches the combined length of the first water chamber 11 and second water chamber 12.

In the embodiments of the present invention, the water tank 2 is equipped with the pump 3 positioned at the location of the outlet tube 41.

Specifically, the pump 3 includes a positioning base 31 recessed from the water tank 2 towards the outlet tube 41, the positioning base 31 is equipped with the positioning groove 32 with the magnetic sensing coil 33, the positioning base 31 pivotally supports the impeller 34, the impeller 34 has the upward-extending surrounding portion 35, the surrounding portion 35 is located at the outer peripheral wall of the positioning base 31. the impeller 34 is pivotally mounted at the center of the positioning base 31, and the surrounding portion 35 has a stator that cooperates with the magnetic sensing coil 33, thereby enabling the installation of brushless motors, with greater and more stable flow pressure.

The above mentioned is only preferred embodiments of the invention, but does not limit the scope of the patent of the invention, and equivalent structure conversion made through the contents of the specification and the attached figures or direct/indirect application to other relevant technical fields under the conception of the invention are included in the scope of patent protection of the invention.

What is claimed is:

1. A water-cooling radiator structure with a pump module, comprising:
A radiator, which includes multiple water pipes spaced apart and two water chambers connecting both ends of the water pipes. The two water chambers include the first water chamber and the second water chamber, and heat dissipation fins are installed between the water pipes;
A water tank, which has a length that matches either the length of the water chamber or the length of the water pipes, and is located at least at the first water chamber and/or the second water chamber, or connects the two water chambers;
The water tank is detachable and is equipped with a pump that provides driving force to the fluid within the water tank.

2. The water-cooling radiator structure with a pump module according to claim 1, wherein the water tank is located on the upper wall or the outer side wall of the water chamber, and the outer side wall includes the side wall of the water chamber that is away from the water pipes or the end walls at both ends of the water chamber.

3. The water-cooling radiator structure with a pump module according to claim 1, wherein the water tank is equipped with spaced inlet tube and outlet tube on its wall, and the water chamber is equipped with inlet guiding hole and outlet guiding hole that match the inlet and outlet tubes. The inlet tube can be inserted into the inlet guiding hole, and the outlet tube can be inserted into the outlet guiding hole.

4. The water-cooling radiator structure with a pump module according to claim 3, wherein the first water chamber is equipped with inlet tube and outlet tube. The first inner chamber of the first water chamber is equipped with the first partition, and the second water chamber is equipped with spaced cooling outlet passage and cooling inlet passage.

5. The water-cooling radiator structure with a pump module according to claim 1, wherein the second inner chamber of the second water chamber is equipped with the second partition.

6. The water-cooling radiator structure with a pump module according to claim 1, wherein the adjacent water pipes are connected end-to-end in series.

7. The water-cooling radiator structure with a pump module according to claim 4, wherein the water pipes are arranged in two groups, including a hot end water pipe group and a cold end water pipe group.

8. The water-cooling radiator structure with a pump module according to claim 4, wherein the length of the water tank matches the sum of the lengths of the first water chamber and the second water chamber.

9. The water-cooling radiator structure with a pump module according to claim 1, wherein the water tank is equipped with a pump located at the position of the outlet tube.

10. The water-cooling radiator structure with a pump module according to claim 9, wherein the pump includes a positioning base recessed from the water tank towards the outlet tube, the positioning base is equipped with a positioning groove with a magnetic sensing coil, the positioning base pivotally supports an impeller, the impeller has an upward-extending surrounding portion, the surrounding portion is located at the outer peripheral wall of the positioning base. The impeller is pivotally mounted at the center of the positioning base, and the surrounding portion has a stator that cooperates with the magnetic sensing coil.
